(19) United States
(12) Patent Application Publication
(10) Pub. No.: US 2010/0121596 A1
(43) Pub. Date: May 13, 2010

(54) METHODS AND SYSTEMS FOR FREQUENCY ESTIMATION FOR ACCELEROMETERS

(75) Inventors: Manuel I. Rodriguez, St. Petersburg, FL (US); Karl Becker, Riverview, FL (US); Nicholas Lyn-Sue, Seminole, FL (US); Jamal Haque, Clearwater, FL (US)

Correspondence Address: HONEYWELL/BLG;Patent Services, 101 Columbia Road, PO Box 2245, Morristown, NJ, 07962-2245, US

(73) Assignee: HONEYWELL INTERNATIONAL INC., Morristown, NJ (US)

(21) Appl. No.: 12/269,679

(22) Filed: Nov. 12, 2008

(51) Int. Cl. G01R 23/00; H04B 15/00

(52) U.S. Cl. 702/75; 702/190

(57) ABSTRACT

Methods and systems for improving frequency estimation without increasing digital counter resolution. An example system mixes and filters a known carrier signal with the signal containing the frequency of interest, in order to bring the frequency domain image closer to baseband, and then performs the frequency estimation. This allows much better resolution without the need to increase the counter frequency.

### BACKGROUND OF THE INVENTION

Some accelerometers require a high accuracy frequency estimation of an output waveform. The better the quality of the frequency estimation, the better the ability to accurately estimate acceleration. One of the problems associated with frequency estimation using digital counters is that resolution is limited by the counter frequency.

### SUMMARY OF THE INVENTION

The present invention provides a way to improve the frequency estimation without increasing the counter resolution. The invention mixes and filters a known carrier signal with the signal containing the frequency of interest, in order to bring the frequency domain image closer to baseband, and then performs the frequency estimation. This allows for much better resolution without the need to increase the counter frequency.

### BRIEF DESCRIPTION OF THE DRAWINGS

Preferred and alternative embodiments of the present invention are described in detail below with reference to the following drawings:

FIG. 1 is a block diagram of a portion of a resonating beam accelerometer system;

FIG. 2 illustrates a block diagram of a frequency estimation device included in the system shown in FIG. 1; and

FIGS. 3-7 illustrate an example of time and frequency domain signals at various stages within the frequency estimation device of FIG. 2.

### DETAILED DESCRIPTION OF THE INVENTION

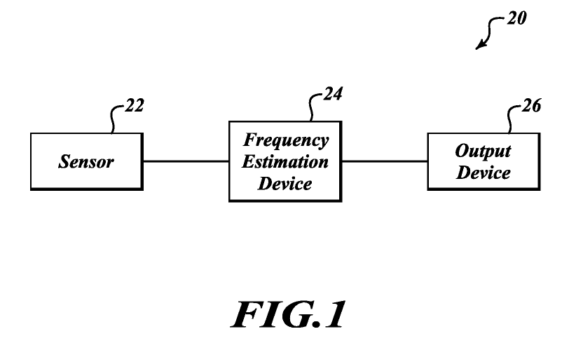

The present invention provides for accurate frequency estimation of a resonating beam sensor, such as a double-ended tuning fork. As shown in FIG. 1, an example system 20 includes a sensor 22, a frequency estimation device 24, and an output device 26. The sensor 22 outputs a signal to the frequency estimation device 24. The frequency estimation device 24 estimates the frequency of the received signal and outputs that value to the output device 26.

The frequency estimation device 24 receives the signal from the sensor 22, process it by mixing it down, filtering it, and digitizing it. The digitized signal is then processed by a digital circuit included in the device 24 which includes a counter in order to estimate the frequency of the mixed down signal. The frequency by which the signal from the sensor 22 was mixed down is then added to the digitally estimated frequency in order to produce an accurate estimate. The frequency estimation is significantly more accurate for the mixed down signal than it would be for the original signal from sensor 22 because the digital counter resolution would be better in estimating the mixed down signal than the original.

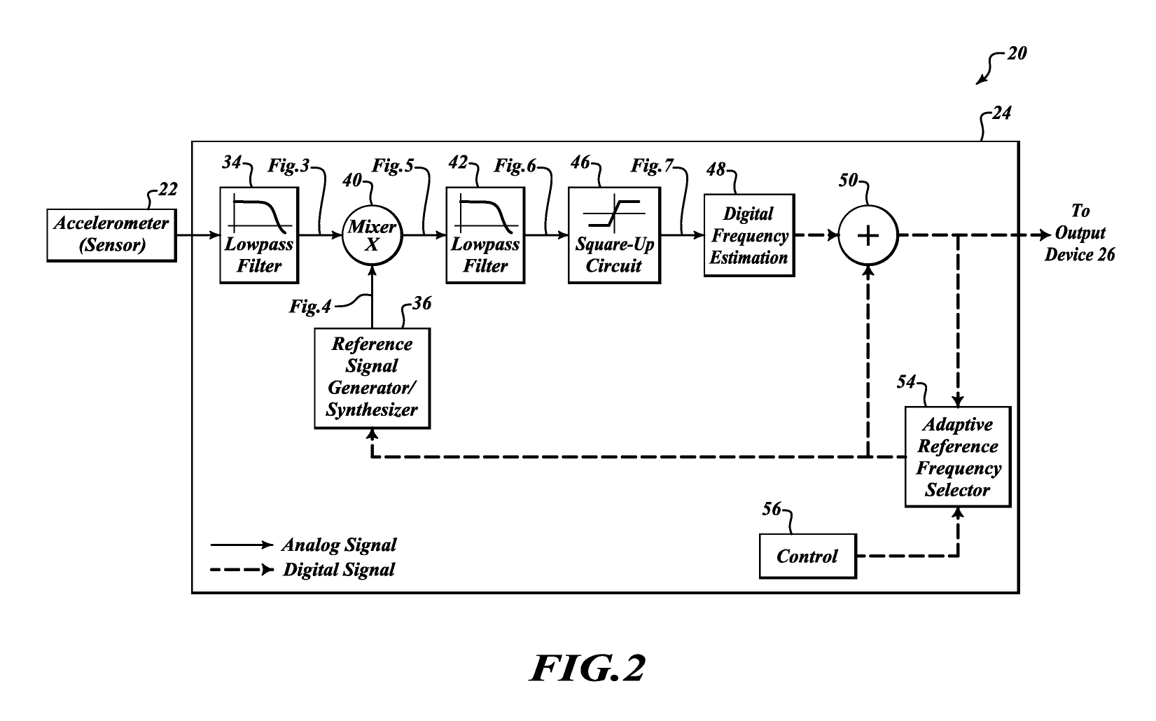

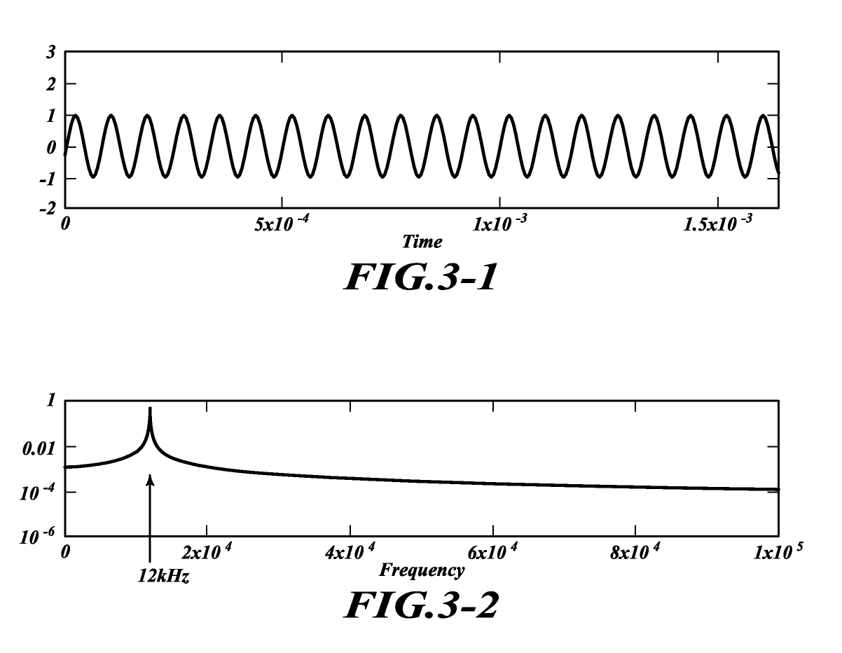

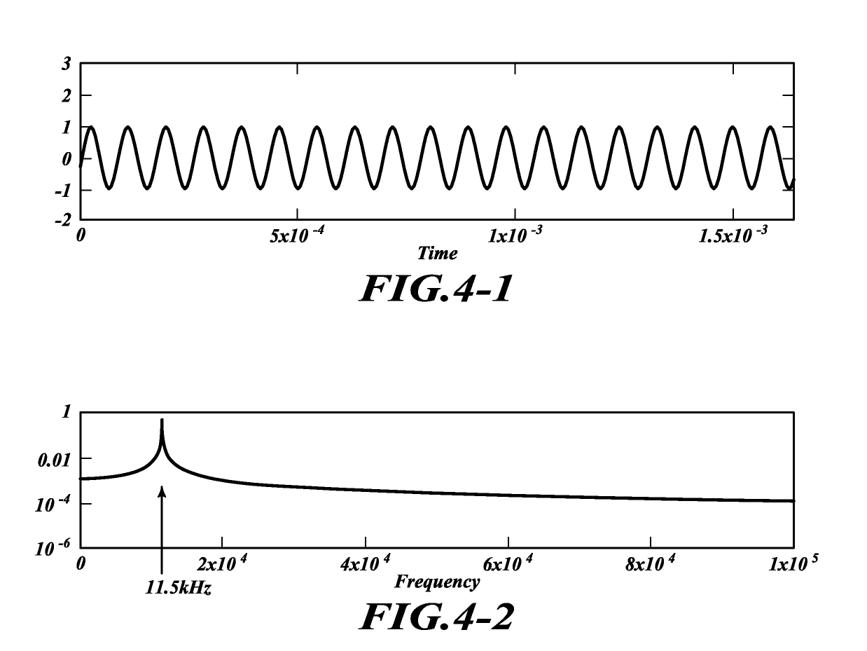

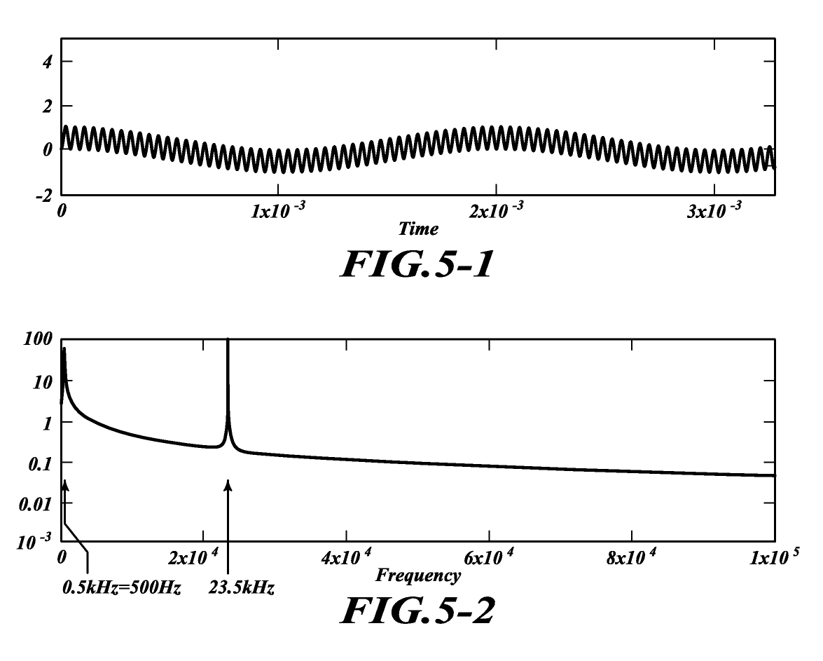

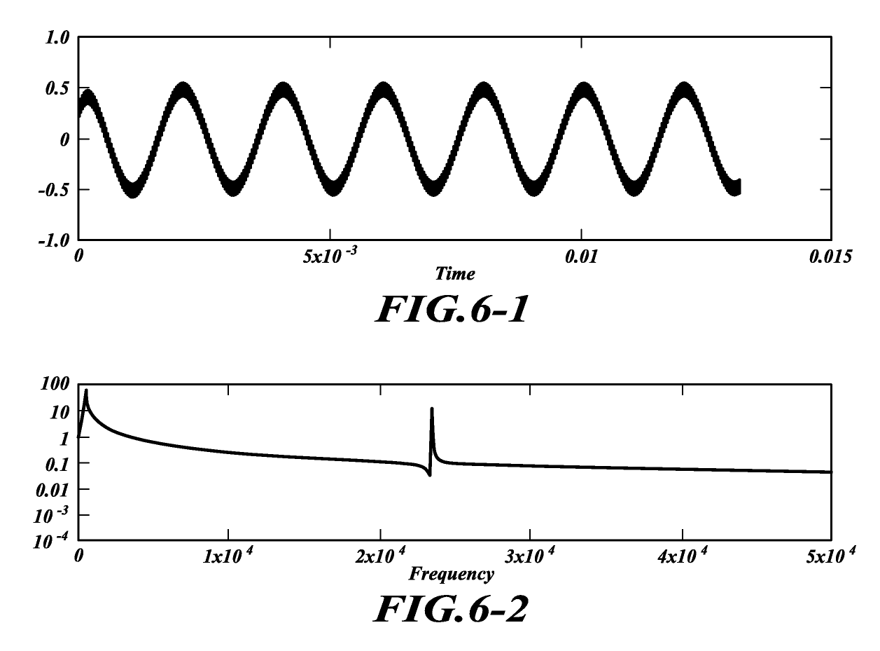

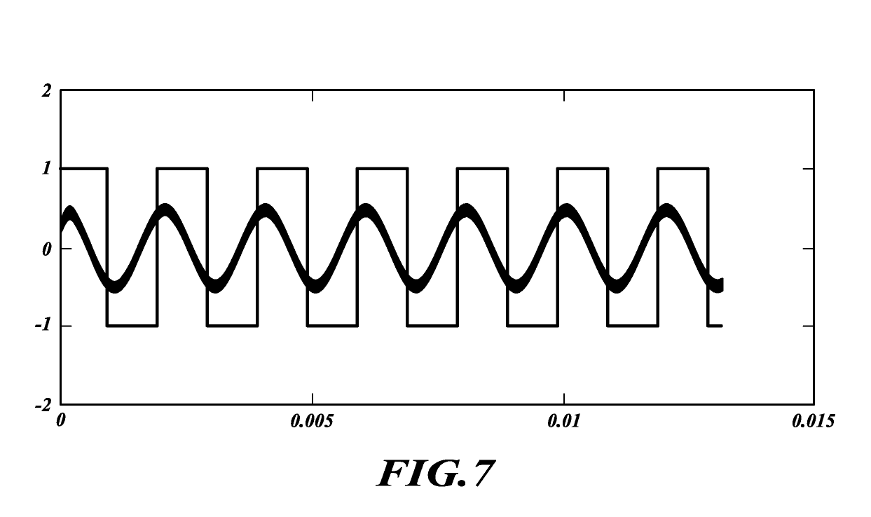

FIG. 2 illustrates an embodiment of the frequency estimation device 24. The frequency estimation device 24 receives the sensor signal from the sensor 22 at a (optional) first low pass filter 34. A reference signal generated by generator/synthesizer 36 is mixed with the output of the first low pass filter 34 at a mixer 40. This first low pass filter is designed to block frequencies above the range permitted by the mixer 40. The synthesizer 36 generates the reference signal (analog) based on a frequency value (digital) sent from the adaptive reference frequency selector 54. An example of the output of the low pass filter 34 is illustrated in FIG. 3 in both the time and frequency domains. An example reference signal is illustrated in FIG. 4. The output of the mixer 40 (example shown in FIG. 5) is sent to a second low pass filter 42. Because the output of the mixer 40 includes both a high and low frequency components, the second low pass filter 42 is set in order to filter out the high frequency component. An example signal in the time and frequency domains outputted by the second low pass filter 42 is illustrated in FIG. 6. Next, at a square-up circuit 46 the output of the second low pass filter 42 is converted into a square wave, such as that shown by example in FIG. 7. A digital frequency estimation component 48, such as a digital counter, then determines the frequency of the output of the square-up circuit 46 and sends that determination to a summation device 50 that combines it with the frequency value originally sent to the synthesizer 36 by the adaptive reference frequency selector 54.

The output of the summation device 50 is now an accurate value of the frequency of the original signal that was received from the sensor 22. The output of the summation device 50 is then sent to one or more output devices 26 and to the adaptive reference frequency selector 54 that is controlled by a controller 56.

In one example, the controller 56 determines how often to change the reference frequency. This may be desired if the sensor signal needed to be tracked more closely. The controller 56 can select the reference frequency that is optimum for the mixer operation.

In one embodiment, the adaptive reference frequency selector 54 receives the output of summation device 50 in order to adjust the reference frequency for optimum mixer operation.

Frequency mixing of two signals (at the mixer 40) is equivalent to multiplying 2 signals in the time domain. The result of the multiplication is two components: one component has a frequency equal to the sum of the two input frequencies; and the other component has a frequency equal to the difference of the two input frequencies. In one example, the signal of interest is band limited (e.g., 1 kHz) and its center frequency is known e.g., 15 kHz). The signal of interest (signal from sensor) is used as the first input to the mixer 40. The second input to the mixer 40 is generated by the synthesizer 36) to be a single sinusoid whose frequency exceeds the center frequency of the signal of interest by about a factor of two times (or greater) the bandwidth of the signal of interest (15 kHz+[1 kHz×2]=17 kHz) to prevent aliasing. After mixing, the two components that are generated are the sum of the two input frequencies (15 kHz+17 kHz=32 kHz) and the difference of the two input frequencies (17 kHz−15 kHz=2 kHz). The mixed signal is then filtered to remove the higher frequency component (the 32 kHz component). The resulting filtered signal (2 kHz) is used for frequency estimation. This process allows for a better frequency estimation, since the digital counter resolution is better for a low frequency component (2 kHz) than for a higher frequency component (15 kHz).

While the preferred embodiment of the invention has been illustrated and described, as noted above, many changes can be made without departing from the spirit and scope of the invention. Accordingly, the scope of the invention is not limited by the disclosure of the preferred embodiment. Instead, the invention should be determined entirely by reference to the claims that follow.

The embodiments of the invention in which an exclusive property or privilege is claimed are defined as follows:

1. A method for estimating frequency of an analog signal outputted by a resonating beam sensor, the method comprising:
mixing the analog signal outputted by the resonating beam sensor with an analog reference signal;
removing a higher of two frequency components included in the mixed signal;
digitizing the signal remaining after the removal;
determining frequency of the digitized signal; and
adding a frequency value that corresponds to the analog reference signal to the determined frequency.

2. The method of claim 1, wherein removing comprises filtering out the higher frequency component.

3. The method of claim 1, further comprising filtering the outputted analog signal before mixing with the analog reference signal.

4. The method of claim 1, further comprising adjusting the analog reference signal based on a control signal.

5. The method of claim 4, wherein the control signal is based on the result of adding the frequency value that corresponds to the analog reference signal to the determined frequency.

6. A device for estimating frequency of a signal outputted by a resonating sensor, the device comprising:
a mixer configured to mix an analog signal received from the resonating sensor and an analog reference signal;
a first filter configured to remove a higher frequency component of the output of the mixer;
a digital counter device configured to determine a frequency value of the signal remaining after removal by the first filter; and
a component configured to add the determined frequency value with a frequency value associated with the reference analog signal, thereby producing an estimate of frequency of the sensor signal.

7. The device of claim 6, wherein the analog reference signal is based on capabilities of the digital counter device.

8. The device of claim 6, further comprising a second filter for filtering the analog signal before being sent to the mixer.

9. The device of claim 6, wherein the digital counter device comprises a square wave generator configured to generate a square wave of the signal remaining after removal by the filter.

10. The device of claim 9, wherein the digital counter device comprises a digital counter configured to determine the frequency value by analyzing the generated square wave.

11. The device of claim 6, wherein the component comprises a summation device.

12. The device of claim 6, further comprising a reference signal frequency selector.

13. The device of claim 12, further comprising a controller configured to control operation of the reference signal frequency selector based on the result of adding the frequency value that corresponds to the analog reference signal to the determined frequency.

14. A system for estimating frequency of an analog signal outputted by a resonating beam sensor, the method comprising:
a means for mixing the analog signal outputted by the resonating beam sensor with an analog reference signal;
a means for removing a higher of two frequency components included in the mixed signal;
a means for digitizing the signal remaining after the removal;
a means for determining frequency of the digitized signal; and
a means for adding a frequency value that corresponds to the analog reference signal to the determined frequency.

15. The system of claim 14, wherein the means for removing comprises a means for filtering out the higher frequency component.

16. The system of claim 14, further comprising a means for filtering the outputted analog signal before mixing with the analog reference signal.

17. The system of claim 14, further comprising a means for adjusting the analog reference signal based on a control signal.

18. The system of claim 17, wherein the control signal is based on the result of adding the frequency value that corresponds to the analog reference signal to the determined frequency.
